(19) United States
(12) Patent Application Publication
(10) Pub. No.: US 2010/0237378 A1
(43) Pub. Date: Sep. 23, 2010

(54) LIGHT EMITTING DIODE PACKAGE STRUCTURE AND FABRICATION THEREOF

(76) Inventors: Tzu-Han LIN, Hsinchu (TW); Wu-Cheng Kuo, Hsinchu (TW); San-Yuan Chung, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/407,363

(22) Filed: Mar. 19, 2009

(51) Int. Cl. H01L 33/00

(52) U.S. Cl. 257/99; 257/E33.056

(57) ABSTRACT

An ultraviolet light emitting diode package structure is disclosed, comprising a substrate with a through-silicon via (TSV) disposed therein, a first electrode disposed on a top side of the substrate, and a second electrode disposed on a bottom side of the substrate, wherein the first electrode and the second electrode are electrically connected through the TSV, an ultraviolet light emitting diode bonded to the top side of the substrate, and a cover substrate bonded to the substrate, wherein the cover substrate comprises a cavity for receiving the ultraviolet light emitting diode.

### BACKGROUND OF THE INVENTION

1. Field of the Invention

The invention relates to a light emitting diode package structure and process.

2. Description of the Related Art

Consideration has been given to using single color LED's, such as red, blue or green LED's, in combination with fluorescent and phosphorescent materials to produce other desired colors. While certain materials respond fluorescently or phosphorescently to light from the visible portion of the light spectrum, and thus respond as visible LED's, there are a number of materials which respond to the relatively higher-energy photons emitted in the ultraviolet portion of the light spectrum.

The technology of light emitting diodes has rapidly developed in recent years from indicators to illumination applications. With the features of long-term reliability, environment friendliness and low power consumption, the LED is viewed as a promising alternative for future lighting products. FIG. 1 shows a conventional package of a LED. A light emission chip 102 is bonded to a plate of a first electrode 104. A resin 108 is applied as a sealant enclosure for the entire structure, including the first electrode 104, the second electrode 106 and the LED die 102, to form a finished LED product. The conventional art, however, cannot be used in wafer-level packaging, in which the wafer is cut after packaged, and the reliability of the conventional LED package is not good enough for high power LEDs.

### BRIEF SUMMARY OF INVENTION

According to the issues described, the invention provides an light emitting diode package structure, comprising a substrate with a through-silicon via (TSV) disposed therein, a first electrode disposed on a top side of the substrate, and a second electrode disposed on a bottom side of the substrate, wherein the first electrode and the second electrode are electrically connected through the TSV, an light emitting diode bonded to the top side of the substrate, and a cover substrate bonded to the substrate, wherein the cover substrate comprises a cavity for receiving the ultraviolet light emitting diode.

The invention further provides an light emitting diode package structure, comprising a substrate, a first electrode disposed on a top side of the substrate, an light emitting diode bonded to the top side of the substrate, and a cover substrate with a cavity bonded to the substrate by an eutectic bonding.

### BRIEF DESCRIPTION OF DRAWINGS

The invention can be more fully understood by reading the subsequent detailed description and examples with references made to the accompanying drawings, wherein:

FIG. 1 shows a conventional ultraviolet light emitting diode package structure.

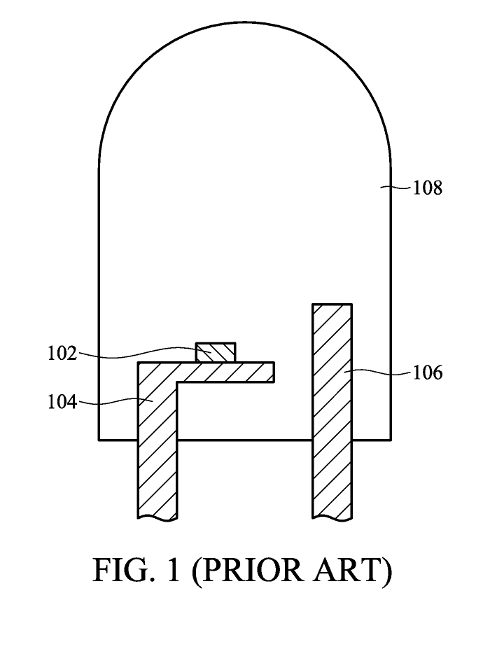

FIGS. 2A˜2D show a wafer-level package process of a light emitting diode of an embodiment of the invention.

FIGS. 3A˜3D show a wafer-level package process of a light emitting diode of another embodiment of the invention.

FIGS. 4A˜4D show a wafer-level package process of a light emitting diode of further another embodiment of the invention.

FIGS. 5A˜5D show a wafer-level package process of a light emitting diode of yet another embodiment of the invention.

### DETAILED DESCRIPTION OF INVENTION

The following descriptions are of the contemplated mode of carrying out the invention. The descriptions are made for the purpose of illustrating the general principles of the invention and should not be taken in a limiting sense, not for limiting the invention.

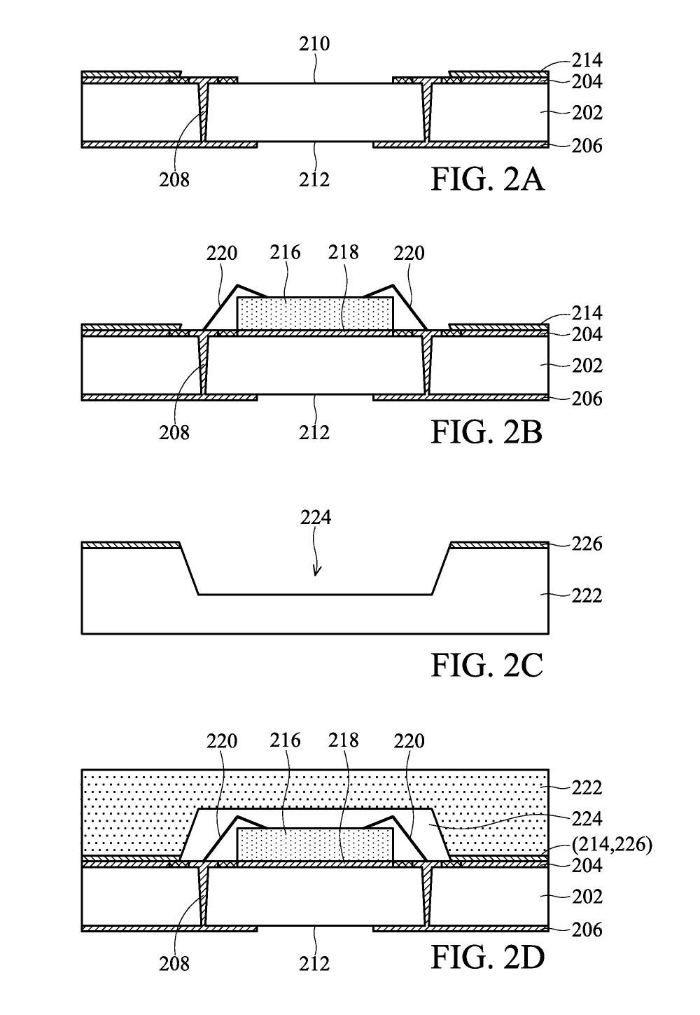

FIGS. 2A˜2D show a wafer-level package of a light emitting diode of an embodiment of the invention. First, referring to FIG. 2A, a substrate 202, such as silicon, is provided. The substrate 202 is drilled or etched and followed by a deposition process, such as be evaporation or sputtering, to form a through-silicon via 208 (TSV) in the substrate 202, a first electrode 204 on the top side 210 of the substrate 202 and a second electrode 206 on the bottom side 212 of the substrate 202. It is noted that the first electrode 204 is electrically connected to the second electrode 206 through the TSV 208. Next, a deposition process, such as an electroplating, evaporating or sputtering deposition process, is performed to form a first solder layer 214 on the first electrode 204 and the substrate 202. In the embodiment, the first solder layer 214 can comprise SnAu, which preferably contains Sn 20% and Au 80%. Referring to FIG. 2B, a light emitting diode (LED) die 216 is bonded to the substrate 202 through an adhesion layer 218, such as a silver glue adhesion layer. Alternatively, the LED die 216 can be bonded to the substrate 202 by an eutectic bond using solder as a bonding material. Next, a wire bonding process is performed to electrically connect the pad (not shown) of the LED die 216 to the first electrode 204 on the substrate 202 through the bonding wire 220. In this aspect, the electrode of the LED die 216 can electrically connect to the first electrode 204 on the top side 210 of the substrate 202 and the second electrode 206 on the bottom side 212 of the substrate 202 through the TSV 208. Referring to FIG. 2C, a cover substrate 222, such as glass, is provided, followed by performing a drilling or etching process to form a cavity 224 in the substrate 202, wherein the cavity 224 can be circular, square or other shapes in the embodiment. Thereafter, a deposition process, such as an electroplating, evaporating or sputtering deposition process, is performed to form a second solder layer 226 on the cover substrate 222. Note that one of the first and second solder layers 214, 226 can be replaced by a wettable metal layer, for example, the metal layer can comprise Au, Ag, Ni or Cu. Referring to FIG. 2D, the substrate 202 and the cover substrate 222 are inputted into a chamber (not shown) and heated to a certain degree, such as 300° C., for the substrate 202 to be bonded with the cover substrate 222 through eutectic bonding. Note that eutectic bonding can increase bonding strength and reliability of the package of the LED device. In an embodiment of the invention, before bonding the substrate 202 and the cover substrate 222, the chamber is vacuumed. Thus, the cavity 224 between the substrate 202 and the cover substrate 222 is a vacuum allowing good and stable emitting quality of the LED for a long duration. In another embodiment of the invention, before bonding the substrate 202 and the cover substrate 222, the chamber is inlet with noble gas and thus the cavity 224 between the substrate 202 and the cover substrate 222 is filled with noble gas.

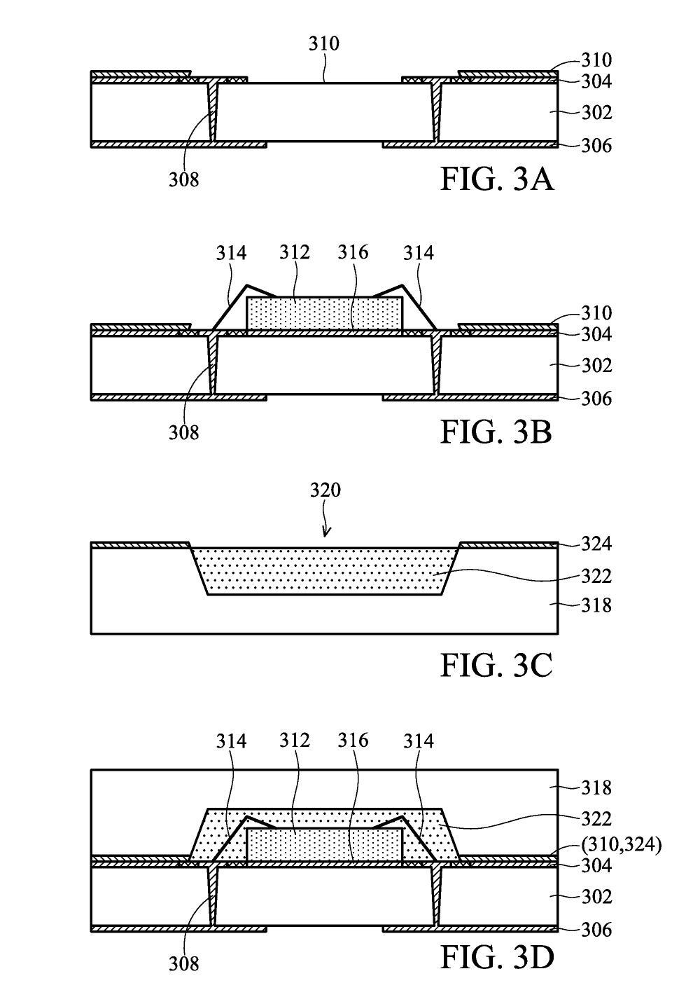

FIGS. 3A˜3D show a wafer-level package of a light emitting diode of an embodiment of the invention. Unlike the embodiment shown in FIGS. 2A˜2D, this embodiment fills UV resistant material or optical fluid material into the cavity between the substrate and the cover substrate. First, referring to FIG. 3A, a substrate 302, such as silicon, is provided. The substrate 302 is drilled or etched and followed by a deposition process, such as an evaporation or sputtering process, to form a through-silicon via 308 (TSV) in the substrate 302, a first electrode 304 on the top side of substrate 302 and a second electrode 306 on the bottom side of the substrate 302. It is noted that the first electrode 304 electrically connects to the second electrode 306 through the TSV 308. Next, a deposition process, such as an electroplating, evaporating or sputtering disposition process, is performed to form a first solder layer 310 on the first electrode 304 and the substrate 302. In the embodiment, the first solder layer 310 can comprise SnAu, which preferably contains 20% Sn and 80% Au. Referring to FIG. 3B, a light emitting diode (LED) die 312 is bonded to the substrate 302 through an adhesion layer 316, such as silver glue adhesion layer. Alternatively, the LED die 312 can be bonded to the substrate 302 by an eutectic bond using solder as a bonding material. Next, a wire bonding process is performed to electrically connect the pad (not shown) of the LED die 312 to the first electrode 304 on the substrate 302 through the bonding wire 314. In this aspect, the electrode of the LED die 312 can electrically connect to the first electrode 304 on the top side of the substrate 302 and the second electrode 306 on the bottom side of the substrate 302 through the TSV 308. Referring to FIG. 3C, a cover substrate 318, such as glass, is provided, followed by performing a drilling or etching process to form a cavity 320 in the cover substrate 318. Thereafter, the cavity 320 is filled with UV resistant material 322, such as UV resistant epoxy or UV resistant silicone, or optical fluid material which preferably has high refraction index for increasing brightness of the LED device. In an example of the invention, the UV resistant material 322 is EG-6301 of DOW CORNING company. In the example of the invention, the optical fluid material 322 is LS-5257 of NuSil company. Next, a deposition process, such as an electroplating, evaporating or sputter deposition process, is performed to form a second solder layer 324 on the cover substrate 318. Note that one of the first and second solder layers 310, 324 can be replaced by a wettable metal layer, for example, the metal layer can comprise Au, Ag, Ni or Cu. Referring to FIG. 3D, the substrate 302 and the cover substrate 318 are inputted into a chamber and heated to a certain degree, such as 300° C., for the substrate 302 to be bonded with the cover substrate 318 through eutectic bonding. Note that the eutectic bonding can increase bonding strength and reliability of the package of the LED device, and the UV resistant material or optical fluid material with high refraction index can increase brightness of the LED package.

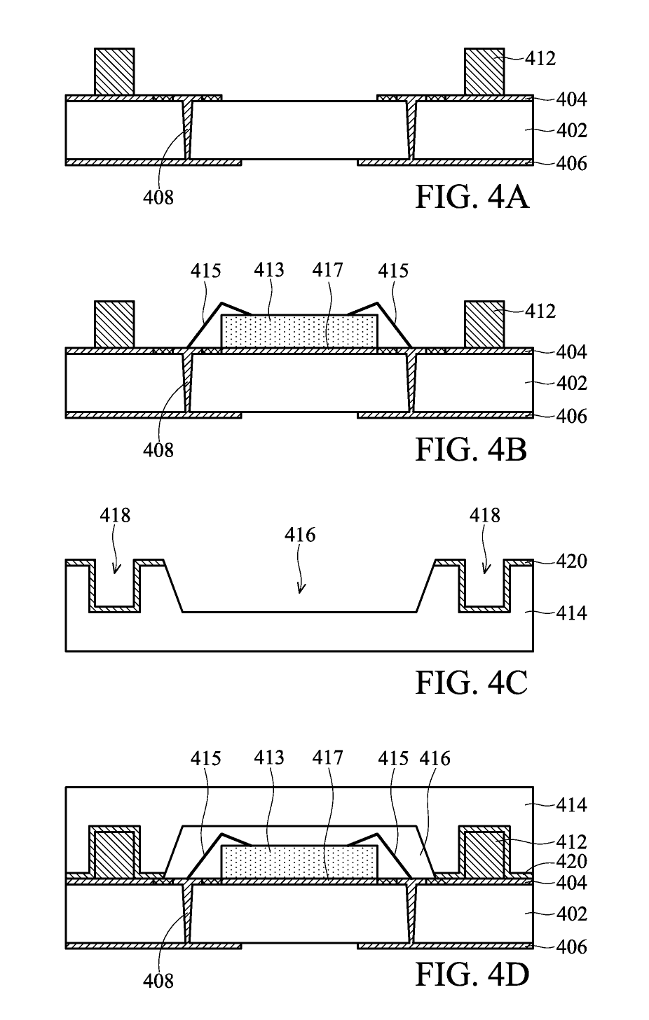

FIGS. 4A˜4D show a wafer-level package of a light emitting diode of further another embodiment of the invention. Unlike the embodiment shown in FIGS. 2A˜2D, the embodiment forms tenons between the substrate and the cover substrate to increase bonding stress and reliability. First, referring to FIG. 4A, a substrate 402, such as silicon, is provided. The substrate 402 is drilled or etched and followed by performing a deposition process, such as an evaporation or sputtering deposition process, to form a through-silicon via 408 (TSV) in the substrate 402, a first electrode 404 on the top side of substrate 402 and a second electrode 406 on the bottom side of the substrate 402. It is noted that the first electrode 404 electrically connects to the second electrode 406 through the TSV 408. Next, a deposition process, such as an electroplating, evaporating or sputter deposition process, is performed to form a tenons 412 and a first solder layer 410 on the first electrode 404 and the substrate 402. In the embodiment, the tenons 412 and the first solder layer 410 can comprise SnAu, which preferably contains Sn 20% and Au 80%. For example, the embodiment can use an electroplating process to deposit solder material to a sufficient thickness, followed by patterning of the solder material to form the tenons 412. Referring to FIG. 4B, a light emitting diode (LED) die 413 is bonded to the substrate 402 through an adhesion layer 417, such as a silver glue adhesion layer. Alternatively, the LED die 413 can be bonded to the substrate 402 by an eutectic bond using solder as a bonding material. Next, a wire bonding process is performed to electrically connect the pad (not shown) of the LED die 413 to the first electrode 404 on the substrate 402 through the bonding wire 415. In this aspect, the electrode of the LED die 413 can electrically connect to the first electrode 404 on the top side of the substrate 402 and the second electrode 406 on the bottom side of the substrate 402 through the TSV 408. Referring to FIG. 4C, a cover substrate 414, such as glass, is provided, followed by performing a drilling or etching process to form a cavity 416 and a plurality of apertures 418 in the cover substrate 414. Thereafter, a deposition process, such as an electroplating, evaporating or sputter deposition process, is performed to form a solder layer 420 on the cover substrate 414 and in the apertures 418. Note that one of the first and second solder layers 404, 420 can be replaced by a wettable metal layer, for example, the metal layer can comprise Au, Ag, Ni or Cu. Referring to FIG. 4D, the substrate 402 and the cover substrate 414 are inputted into a chamber and heated to a certain degree, such as 300° C., for the substrate 402 to be bonded with the cover substrate 414 through eutectic bonding and the tenons 412 on the substrate 402 are joined by the apertures 418 in the cover substrate 414. Note that bonding strength and reliability of the package of the LED device is further increased with the tenons 412.

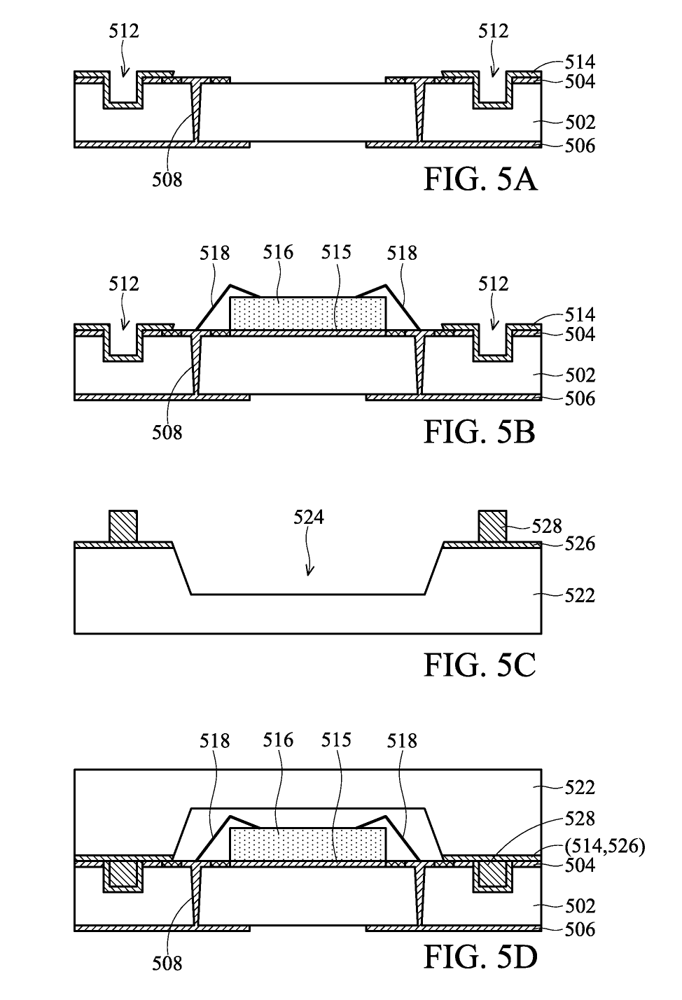

FIGS. 5A˜5D show a wafer-level package of a light emitting diode of yet another embodiment of the invention. Unlike the embodiment shown in FIGS. 4A˜4D, the embodiment forms tenons on the cover substrate and the substrate is drilled or etched to form apertures for the tenons to be joined. First, referring to FIG. 5A, a substrate 502, such as silicon, is provided. The substrate 502 is drilled or etched and followed by performing a deposition process, such as an evaporation or sputtering deposition process, to form a through-silicon via 508 (TSV) in the substrate 502, a first electrode 504 on the top side of substrate 502 and a second electrode 506 on the bottom side of the substrate 502. Alternatively, apertures 512 can be formed simultaneously during forming of the TSV 508. Next, a deposition process, such as an electroplating, evaporating or sputter deposition process, is performed to form a first solder layer 514 on the first electrode 504 and the substrate 502 and filled in the apertures 512. In the embodiment, the first solder layer 514 can comprise SnAu, which preferably contains Sn 20% and Au 80%. Referring to FIG. 5B, a light emitting diode (LED) die 516 is bonded to the substrate 502 through an adhesion layer 515, such as silver glue adhesion layer. Alternatively, the LED die 516 can be bonded to the substrate 502 by an eutectic bond using solder as a bonding material. Next, a wire bonding process is performed to electrically connect the pad (not shown) of the LED die 516 to the first electrode 504 on the substrate 502. In this aspect, the electrode of the LED die 516 can electrically connect to the first electrode 504 on the top side of the substrate 502 and the second electrode 506 on the bottom side of the substrate 502 through the TSV 508. Referring to FIG. 5C, a cover substrate 522, such as glass, is provided, followed by performing a drilling or etching process to form a cavity 524 in the substrate 522. Thereafter, a deposition process, such as an electroplating, evaporating or sputter deposition process, is performed to form a second solder layer 526 on the cover substrate 522. In an important feature of the embodiment, not only is the first solder layer 514 formed, but tenons 528 are also formed on the cover substrate 522 during forming of the second solder layer 526. For example, the embodiment can use an electroplating process to deposit the second solder layer 526 to a sufficient thickness, followed by patterning the second solder layer 526 to form the tenons 528. Note that one of the first and second solder layers 514, 526 can be replaced by a wettable metal layer, for example, the metal layer can comprise Au, Ag, Ni or Cu. Referring to FIG. 5D, the substrate 502 and the cover substrate 522 are inputted into a chamber and heated to a certain degree, such as 300° C., for the substrate 502 to be bonded with the cover substrate 522 through eutectic bonding and the tenons 528 on the cover substrate 522 are joined by the apertures 512 in the substrate 502. Note that bonding strength and reliability of the package of the LED device is increased with the tenons 528 in the embodiment.

Note that the aforementioned embodiments only describe processes for the steps of forming a wafer-level package structure. The wafer-level package structure can be further cut to form a plurality of SMT type LED devices.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An light emitting diode package structure, comprising:
a substrate with a through-silicon via (TSV) disposed therein;
a first electrode disposed on a top side of the substrate;
a second electrode disposed on a bottom side of the substrate, wherein the first electrode and the second electrode are electrically connected through the TSV;
an light emitting diode bonded to the top side of the substrate; and
a cover substrate bonded to the substrate, wherein the cover substrate comprises a cavity for receiving the light emitting diode.

2. The light emitting diode package structure as claimed in claim 1, further comprising at least one solder layer between the substrate and the cover substrate.

3. The light emitting diode package structure as claimed in claim 1, wherein the cover substrate is glass.

4. The light emitting diode package structure as claimed in claim 2, wherein the light emitting diode is bonded to the top side of the substrate through eutectic bonding.

5. The light emitting diode package structure as claimed in claim 1, wherein the cavity encloses a vacuum.

6. The light emitting diode package structure as claimed in claim 1, wherein the cavity is filled with noble gas.

7. The light emitting diode package structure as claimed in claim 1, wherein the cavity is filled with UV resistant material.

8. The light emitting diode package structure as claimed in claim 7, wherein the UV resistant material is UV resistant epoxy or UV resistant silicone.

9. The light emitting diode package structure as claimed in claim 1, wherein the cavity is filled with optical fluid or optical gel.

10. The light emitting diode package structure as claimed in claim 1, further comprising tenons between the substrate and the glass substrate.

11. The light emitting diode package structure as claimed in claim 10, wherein the tenons comprise solder.

12. The light emitting diode package structure as claimed in claim 10, wherein the tenons are formed on the substrate, and the cover substrate includes apertures for receiving the tenons.

13. The light emitting diode package structure as claimed in claim 10, wherein the tenons are formed on the cover substrate, and the substrate includes apertures for receiving the tenons.

14. An light emitting diode package structure, comprising:
a substrate;
a first electrode disposed on a top side of the substrate;
an light emitting diode bonded to the top side of the substrate; and
a cover substrate with a cavity bonded to the substrate by an eutectic bonding.

15. The light emitting diode package structure as claimed in claim 14, wherein the light emitting diode package structure comprises a solder layer and a metal wettable to the solder layer between the substrate and the cover substrate.

16. The light emitting diode package structure as claimed in claim 14, wherein the cavity encloses a vacuum.

17. The light emitting diode package structure as claimed in claim 14, wherein the cavity is filled with noble gas.

18. The light emitting diode package structure as claimed in claim 14, wherein the cavity is filled with UV resistant material.

19. The light emitting diode package structure as claimed in claim 18, the UV resistant material is UV resistant epoxy or UV resistant silicone.

20. The light emitting diode package structure as claimed in claim 14, further comprising tenons between the substrate and the glass substrate.

21. The light emitting diode package structure as claimed in claim 20, wherein the tenons comprise solder.
